(19) United States
(12) Patent Application Publication
(10) Pub. No.: US 2010/0300733 A1
(43) Pub. Date: Dec. 2, 2010

(54) Multilayer ceramic board and manufacturing method thereof

(75) Inventors: Yong Suk Kim, Yongin-si (KR); Byeung Gyu Chang, Suwon-si (KR); Won Hee Yoo, Suwon-si (KR); Yong Soo Oh, Seongnam-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD, Suwon (KR)

(21) Appl. No.: 12/458,780

(22) Filed: Jul. 22, 2009

(30) Foreign Application Priority Data
May 28, 2009 (KR) 10-2009-0046954

(51) Int. Cl. H05K 1/09; B05D 5/12; B32B 38/00

(52) U.S. Cl. 174/257; 427/97.3; 156/89.12; 156/89.13

(57) ABSTRACT

The present invention relates to a multilayer ceramic board and manufacturing method thereof. The multilayer ceramic board includes: a ceramic stacked structure in which multiple ceramic layers are stacked and interconnected to one another through vias; diffused reflection preventing patterns which expose the vias provided on each of the uppermost ceramic layer and the lowermost ceramic layer, and are disposed on each of a top surface and a bottom surface of the ceramic stacked structure; and contact pads which are electrically connected to the vias exposed by the diffused reflection preventing patterns.

### CROSS-REFERENCE TO RELATED APPLICATIONS

This application claims the benefit of Korean Patent Application No. 10-2009-0046954 filed with the Korea Intellectual Property Office on May 28, 2009, the disclosure of which is incorporated herein by reference.

### BACKGROUND OF THE INVENTION

1. Field of the Invention

The present invention relates to a multilayer ceramic board and manufacturing method thereof; and, more particularly, to a multilayer ceramic board provided with diffused reflection preventing patterns disposed on each of top and bottom surfaces of a ceramic stacked structure.

2. Description of the Related Art

The recent trend toward technical development of electric apparatus and thinness of the apparatus itself causes essential integration of its components.

There has been developed a multilayer ceramic board formed by stacking a number of ceramic sheets for integration of its components. As the multilayer ceramic board has thermal resistance, abrasion resistance, and superior electric characteristics, it has been widely used as a substitute for the conventional print circuit board. Further, the demand for the multilayer ceramic board has been increased.

The multilayer ceramic board has been used to constitute various electric components, such as a PA module board, an RF diode switch, a filter, a chip antenna, various package components, a complex device, and so on.

Particularly, the multilayer ceramic board may be used in a probe substrate of a probe card used for electrical examination of a semiconductor device. Herein, the probe substrate may be composed of multilayer ceramic board having contact pads provided on an upper part and a lower part thereof. In this case, the contact pads disposed on the lower part of the multilayer ceramic board is in electrical contact with a print circuit board which transmits and receives examination signals from/to an outside. Further, the contact pads disposed on the upper part of the multilayer ceramic board may be in contact with probe pins which are electrically connected to a semiconductor device of being an examination target.

In order to manufacture the multilayer ceramic board, a ceramic stacked structure is first formed by stacking green sheets in multiple layers and undergoing a firing process. Then, contact pads are formed on each of the top surface and the bottom surface of the ceramic stacked structure so as to be electrically interconnected to an outside.

Herein, the contact pads have a uniform pattern which is obtained by undergoing a plating process using resist patterns, which are formed by forming a seed plating layer on the ceramic stacked structure, and performing a photo process on the resultant seed layer.

Further, the formation of probe pins on the contact pads is made through a photo process, and an MEMS process which includes a plating process, and an etching process. Alternatively, the formation of the probe pins on the contact pads is made by forming probe pins on a separate wafer substrate, aligning the contact pads and the probe pins in such a manner to come into contact with each other, and then performing an adhesion process.

In this case, since diffused reflection of lights is generated due to nature of a ceramic material, there has been a problem in performing alignment control required for not only the photo process for forming the contact pads on the multilayer ceramic board, but also the process for forming the probe pins. This mans that the diffused reflection of lights on the multilayer ceramic board causes align marks not to be recognized. This is because the alignment is made after align marks formed on a substrate are recognized through lights.

In order to solve problems, the multilayer ceramic board was manufactured in such a manner that a pigment absorbing lights was included in the green sheets for prevention of the diffused reflection of lights. However, in case where the pigment was included in the multilayer ceramic board, there has been problems that chemical resistance and durability of the multilayer ceramic board were reduced. Thus, the multilayer ceramic board had an inferior strength, and damaged surfaces or damaged vias due to chemicals, such as a strong acid or a strong base used in a photo process or an MEMS process for forming contact pads or probe pins.

Further, due to surface damage of the multilayer ceramic board, sticking strength between the multilayer ceramic board and the contact pads was reduced, and accordingly, electrical leakage resistance was generated.

Furthermore, for example, in case where the probe pins were formed on the multilayer ceramic board in a subsequent process, the surfaces of the multilayer ceramic board was contaminated due to contaminants, i.e. ceramic powder or metal powder, generated by chemicals. In the end, adhesive strength between the multilayer ceramic board and the probe pins was reduced, and electric characteristics of the probe substrate manufactured by using the multilayer ceramic board were lowered.

Moreover, in case where the multilayer ceramic board is formed by a low temperature co-fired ceramics (LTCC), the multilayer ceramic board is vulnerable to the chemicals although it has no pigment included therein, which makes the above-described problem much worse.

Therefore, the multilayer ceramic board has a problem in that there is a difficulty in performing an alignment process due to nature of a ceramic material. In addition, there is a problem of reduction in electric characteristics and reliability of electrical components manufactured by using the multilayer ceramic board vulnerable to the chemicals.

### SUMMARY OF THE INVENTION

The present invention has been invented in order to overcome the above-described problems and it is, therefore, an object of the present invention to provide a multilayer ceramic board having diffused reflection preventing patterns disposed on each of the top and bottom surfaces of a ceramic stacked structure.

In accordance with one aspect of the present invention to achieve the object, there is provided a multilayer ceramic board including: a ceramic stacked structure in which multiple ceramic layers are stacked and interconnected to one another through vias; diffused reflection preventing patterns which expose the vias provided on each of the uppermost ceramic layer and the lowermost ceramic layer, and are disposed on each of a top surface and a bottom surface of the ceramic stacked structure; and contact pads which are electrically connected to the vias exposed by the diffused reflection preventing patterns.

Herein, the diffused reflection preventing patterns may be composed of a Diamond-like carborn (DLC), or a Silicon carbide (SiC).

The method may further include conductive adhesive patterns interposed between the contact pads and the vias.

Also, the conductive adhesive patterns may include at least one of Ni, Ti, and Cr.

Also, the contact pads may include at least one of Cu, Ni, and Au.

In accordance with another aspect of the present invention to achieve the object, there is provided a method of manufacturing a multilayer ceramic board including the steps of: providing a ceramic stacked structure in which multiple ceramic layers are stacked, and are interconnected to one another through vias; forming diffused reflection preventing patterns which expose the vias provided on each of the uppermost ceramic layer and the lowermost ceramic layer, and are disposed on each of a top surface and a bottom surface of the ceramic stacked structure; and forming contact pads which are electrically connected to the vias exposed by the diffused reflection preventing patterns.

Herein, the step of forming the diffused reflection preventing patterns may include the steps of: forming mask patterns which cover the vias provided on each of the uppermost ceramic layer and the lowermost ceramic layer; depositing a diffused reflection preventing material on a top surface and a bottom surface of the ceramic stacked structure having the mask patterns formed thereon; and forming the diffused reflection preventing patterns by removing the mask patterns.

Also, the mask patterns may include at least one of a teflon-based resin and a silicon-based resin.

Also, the step of forming the contact pads may include the steps of: forming plating seed layers on the ceramic stacked structure having the diffused reflection preventing patterns; forming resist patterns on the plating seed layers; and forming the contact pads by performing a plating process on the plating seed layers exposed by the resist patterns.

Also, the method may further include a step of, before the step of forming the plating seed layers, forming conductive adhesive layers on the ceramic stacked structure having the diffused reflection preventing patterns.

Also, the conductive adhesive layers may include at least one of Ni, Ti, and Cr.

Also, the method may further include the steps of, after the step of forming the contact pads; removing the resist patterns; and patterning the conductive adhesive layers and the plating seed layers.

Also, in the step of forming the resist patterns, an align mark may further be formed on an edge of the ceramic stacked structure.

Also, the diffused reflection preventing patterns may be formed of a Diamond-like carborn (DLC), or a Silicon carbide (SiC).

In accordance with another aspect of the present invention to achieve the object, there is provided a method of manufacturing a multilayer ceramic board including the steps of: providing a ceramic stacked structure in which multiple ceramic layers are stacked; stacking green sheets which have vias playing a role of performing interlayer connection between the ceramic stacked structure, and the diffused reflection preventing patterns on each of both sides of the ceramic stacked structure; firing the ceramic stacked structure in which the green sheets are stacked; and forming contact pads electrically connected to the vias exposed by the diffused reflection preventing patterns.

Herein, the step of forming the green sheets includes: forming green sheets having the vias passing therethrough; forming mask patterns which cover the vias on the formed green sheets; depositing a diffused reflection preventing material on the formed green sheets having the mask patterns; and removing the mask patterns.

Also, the mask patterns may include at least one of a teflon-based resin and a silicon-based resin.

Also, the diffused reflection preventing patterns may be formed of a Diamond-like carborn (DLC), or a Silicon carbide (SiC).

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a multilayer ceramic board in accordance with a first embodiment of the present invention;

FIGS. 2 to 9 are cross-sectional views for explaining a method of manufacturing a multilayer ceramic board in accordance with a second embodiment of the present invention;

FIGS. 10 to 12 are cross-sectional views for explaining a method of manufacturing a multilayer ceramic board in accordance with a third embodiment of the present invention;

### DETAILED DESCRIPTION OF THE PREFERABLE EMBODIMENTS

Hereinafter, embodiments of the present invention will be described in detail with reference to the accompanying drawings illustrating a semiconductor package. The following embodiments are provided as examples to allow those skilled in the art to sufficiently appreciate the spirit of the present invention. Therefore, the present invention can be implemented in other types without limiting to the following embodiments. And, for convenience, the size and the thickness of an apparatus can be overdrawn in the drawings. The same components are represented by the same reference numerals hereinafter.

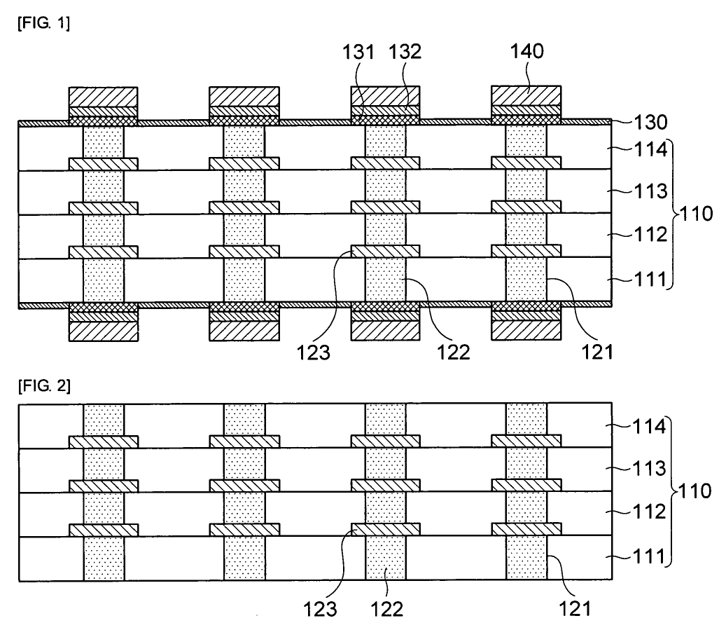

FIG. 1 is a cross-sectional view of a multilayer ceramic board in accordance with a first embodiment of the present invention.

Referring to FIG. 1, a multilayer ceramic board in accordance with the embodiment of the present invention may include a ceramic stacked structure 110, diffused reflection preventing patterns 130, and contact pads 140.

The ceramic stacked structure 110 may include ceramic layers 111, 112, 113, and 114 formed by being stacked in multiple layers. In this case, the ceramic layers 111, 112, 113, and 114 formed by being staked in multiple layers are provided with the vias 122 to allow the layers to be connected to one another, wherein the vias include a conductive material filled in via holes 121 which pass through their bodies, for example, an Ag paste. Also, inner circuit patterns 123 electrically connected to the vias 122 are further provided in the ceramic stacked structure 110.

The diffused reflection preventing patterns 130 expose the vias 122 provided on each of the uppermost ceramic layer 114 and the lowermost ceramic layer 111, and are disposed on each of the top and bottom surfaces of the ceramic stacked structure 110. The diffused reflection preventing patterns 130 may be composed of a material which absorbs lights. Thus, by the diffused reflection preventing patterns 130, even if a pigment is not included in the ceramic stacked structure, alignment can be performed which generally uses lights. Accordingly, it is possible to prevent reduction in chemical resistance of the multilayer ceramic board due to the pigment.

Further, the diffused reflection preventing patterns 130 may be formed of a material, which can have superior chemical resistance, as well as absorb lights, for example, a Diamond-like carborn (DLC), or a Silicon carbide (SiC). Thus, the ceramic stacked structure 110 can be protected from chemicals which are used in a subsequent process, e.g. a photo process, or an MEMS process.

Therefore, it is possible to secure surface durability of the multilayer ceramic board, so that its strength can be maintained even in subsequent manufacturing process, e.g. a photo process, a plating process, and an etching process.

Furthermore, the surface damage of the multilayer ceramic board due to the subsequent processes can be prevented, and thus interfacial adhesion between the ceramic stacked structure 110 and contact pads 140 to be described can be enhanced. Therefore, it is possible to not only achieve prevention of electrical leakage resistance and improvement of RF circuit signal transmission power, but also implement integrated pad line width, resulting in securing design freedom for mounting a resistance, an inductor, and an MLCC.

The contact pads 140 are electrically connected to the vias 122, exposed by the diffused reflection preventing patterns 130, and may be disposed on both sides of the ceramic stacked structure 110, respectively. However, unlike the drawing, the contact pads 140 may be disposed to be further extended on the diffused reflection preventing patterns 130.

The contact pads 140 may be formed of single layer composed of at least one of conductive materials such as Cu, Ni, and Au, or a plurality of layers sequentially stacked with Cu, Ni, and Au.

Herein, in case where the electrical component formed by using multilayer ceramic board is used to form a probe substrate, the contact pads 140 disposed on the top surface of the ceramic stacked structure 110 may come into electrical contact with the print circuit board which receives a feed-back of test signals. Further, other examples of the electrical component include a passive element or a semiconductor IC chip.

Furthermore, in case where a device formed by using the multilayer ceramic board, is used to form a probe substrate, the contact pads 140 disposed on the bottom surface of the ceramic stacked structure 110 may come into electrical contact with probe pins which comes into electrical contact with the semiconductor device of being a test object.

Herein, due to surface protection of the multilayer ceramic board, bonding strength between the ceramic stacked structure 110 and the contact pads 140 is prevented from being reduced, so that it is possible to improve bondability between the multilayer ceramic board and the probe substrate. Thus, leakage resistance between the multilayer ceramic board and the probe pins can be reduced, which results in improvement of electric characteristics of the probe substrate.

Further, conductive adhesive patterns 131 may be further provided between the contact pads 140 and the diffused reflection preventing patterns 130. The conductive adhesive patterns 131 can play a role of improving reliability of the contact pads 140 by enhancing adhesive strength between the diffused reflection preventing patterns 130 and the plating layer for formation of the contact pads 140. Herein, the conductive adhesive patterns 131 may be composed of a material, including at least one of Ti, Ni, and Cr. That is, the conductive adhesive patterns 131 may be formed in a single film, or double film or more. Further, the conductive adhesive patterns 131 may be formed with a single component composed of any one selected from Ti, Ni, and Cr, or may be formed with a mixed component obtained by co-depositing two or more ones selected from Ti, Ni, and Cr.

Further, plating seed patterns 132, which are used as a seed layer to form the contact pads 140 in a plating process, may be further provided between the conductive adhesive patterns 131 and the contact pads 140.

Therefore, the multilayer ceramic board in accordance with the embodiment of the present invention is provided with diffused reflection preventing patterns formed of a material which can prevent a diffused reflection and have superior chemical resistance, so that alignment control can be performed. In addition, chemical resistance and durability of the multilayer ceramic board can be enhanced, and accordingly, it is possible to improve reliability and electric characteristics of electric components formed by using the multilayer ceramic board.

Also, it has been illustrated that the ceramic stacked structure is formed by stacking four ceramic layers, which is provided for illustrative purpose. However, the present invention is not limited thereto.

Hereinafter, a detailed description will be given of a method of manufacturing the multilayer ceramic board in accordance with the first embodiment of the present invention, with reference to FIGS. 2 to 9.

FIGS. 2 to 9 are cross-sectional views for explaining a method of manufacturing the multilayer ceramic board in accordance with the second embodiment of the present invention.

Referring to FIG. 2, in order to manufacture the multilayer ceramic board, the ceramic stacked structure 110 may be provided in which a plurality of ceramic layers 111, 112, 113, and 114 are stacked and interconnected to one another through the vias 112.

The ceramic stacked structure 110 may be formed by allowing green sheets having the vias 122 to be stacked in multiple layers and firing the stacked green sheets. In the stacked green sheets, interlayer connection can be achieved through the vias 122. The green sheets further include inner circuit patterns 123 connected to the vias 122.

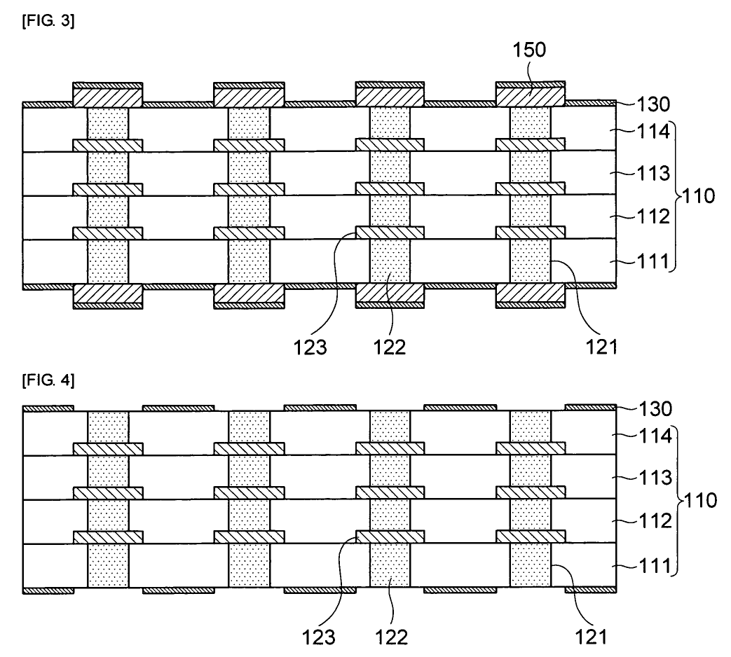

Referring to FIG. 3, mask patterns 150 are formed which cover the vias 122 provided on each of the uppermost ceramic layer 114 and the lowermost ceramic layer 111.

The mask patterns 150 may be formed to correspond to a formation region of the contact pads 140 to be described. The mask patterns 150 may be composed of a resin which can provide durability in the subsequent process, e.g. a deposition process. For example, the resin may include at least one of a teflon-based resin and a silicon-based resin. In this case, the mask patterns 150 may be formed through a printing method, such as a screen printing method, a roll printing method, an imprinting method, and so on.

A diffused reflection material is deposited on the top and bottom surfaces of the ceramic stacked structure 110 having the mask patterns 150. Herein, an example of deposition of the diffused reflection material may include a sputtering method, an e-beam, a CVD and a PVD similar to an ALD method, and so on.

By removing the mask patterns 150, the diffused reflection preventing patterns 130 may be formed which expose the vias 122 provided on each of the uppermost ceramic layer 114 and the lowermost ceramic layer 111 in the ceramic stacked structure 110, as shown in FIG. 4. The mask patterns 150 may be removed through a wet process or a dry process using a laser.

The diffused reflection preventing patterns 130 may be composed of a material, which absorbs lights and has superior chemical resistance, for example, a Diamond-like carborn, or a Silicon carbide (SiC).

Thus, the diffused reflection preventing patterns 130 make it possible to perform an alignment process using lights even though a separate pigment is not included in the ceramic stacked structure 110. As the diffused reflection preventing patterns 130 are formed of a material having a superior chemical resistance, the surfaces of the ceramic stacked structure 110 can be prevented from chemicals which are used in subsequent processes, e.g. a process for removing the mask patterns 150, a photo process, and an MEMS process.

Further, surface durability of the multilayer ceramic board can be secured by the diffused reflection preventing patterns 130, so that strength of the board can be maintained even in the subsequent processes, e.g. a photo process, a plating process, and an etching process.

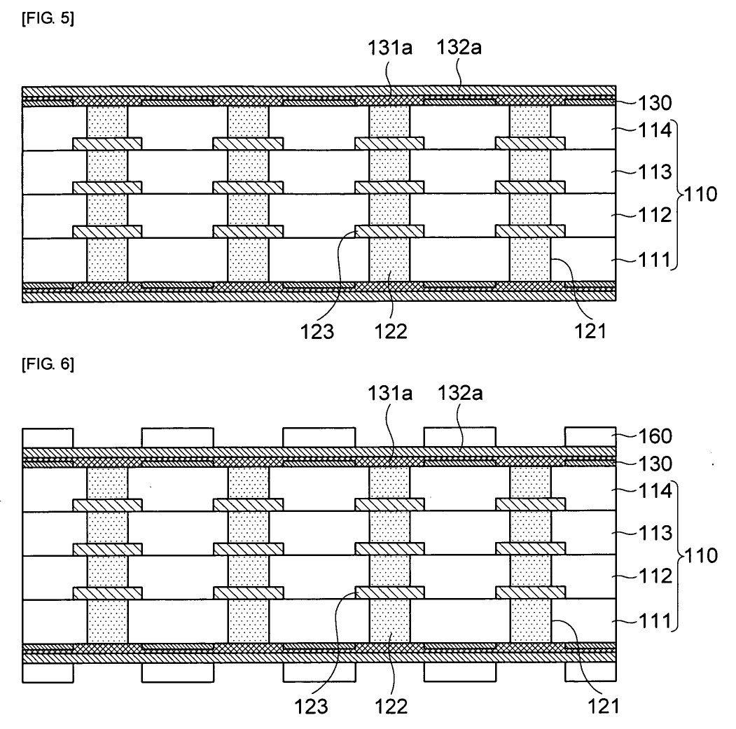

Referring to FIG. 5, conductive adhesive layers 131a and plating seed layers 132a are formed on both sides of the ceramic stacked structure 110 having the diffused reflection preventing patterns 130 in a sequential manner.

The conductive adhesive layers 131a play a role of improving bonding strength between the plating seed layers 132a and the diffused reflection preventing patterns 130. Examples of the conductive adhesive layers 131a may include at least any one, or two or more of Ti, Ni, and Cr.

The plating seed layers 132a play a role of serving as a seed for formation of the contact pads 140 which are to be described. As for a material of the plating seed layers 132a, Cu may be exemplified.

Referring to FIG. 6, resist patterns 160 are formed on the plating seed layers 132a. The resist patterns 160 are formed by forming a photo resist film on the plating seed layers 132a or attaching a dry film prior to performing an exposing process and a developing process. In this case, although not shown in the drawing, an align key may be further formed on periphery of the ceramic stacked structure 110 in the step of forming the resist patterns 160. Herein, the align key may be used for the alignment of the contact pads 140 and the probe pins in a bonding process for forming the probe pins.

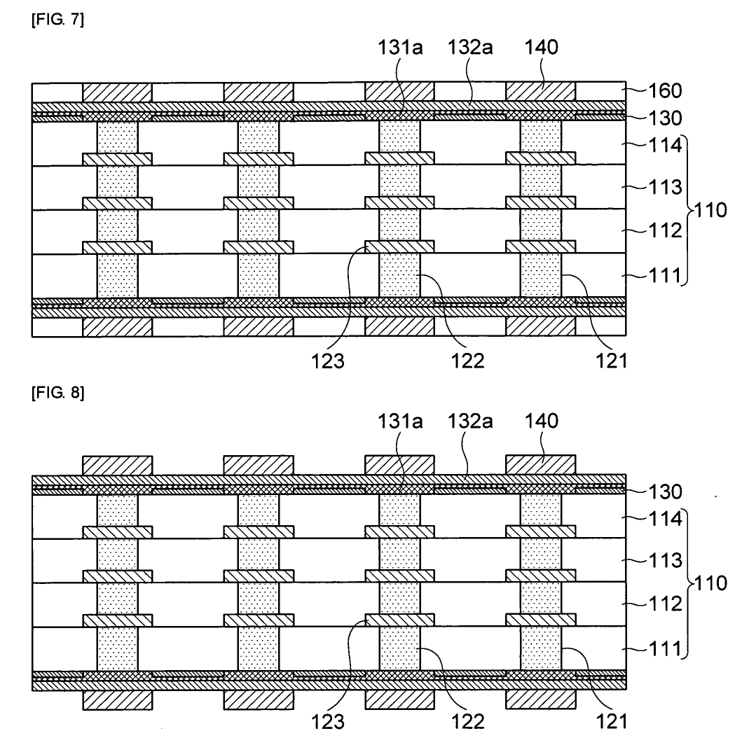

Referring to FIG. 7, the contact pads 140 are formed by performing a plating process on the plating seed layers 132a exposed by the resist patterns 160. Herein, the contact pads 140 may be formed of a single layer composed of at least one of conductive materials, e.g. Cu, Ni, and Au, or multiple layer formed by being sequentially plated with Cu, Ni, and Au.

After forming the contact pads 140, the resist patterns 160 can be removed as shown in FIG. 8.

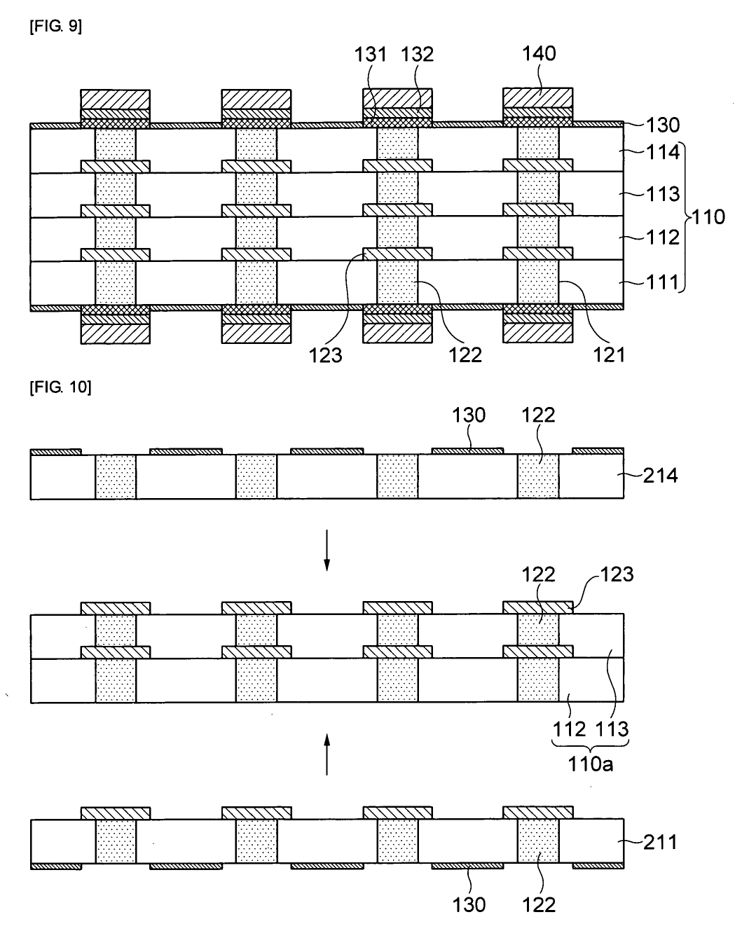

Referring to FIG. 9, the contact pads 140 electrically connected to the vias 122 can be formed by etching the conductive adhesive layers 131a and the plating seed layers 132a using the contact pads 140 as an etching mask. Herein, the etching process may be a wet etching process. In this case, the diffused reflection preventing patterns 130 are provided on each of the top and bottom surfaces of the ceramic stacked structure 110, so that the surfaces of the ceramic stacked structure 110 can be protected from the chemicals used in the wet etching process.

Therefore, the multilayer ceramic board is provided with the diffused reflection preventing patterns which have superior chemical resistance, and absorbs lights, and thus the surfaces of the ceramic stacked structure can be prevented from being damaged in the subsequent processes, which contributes to enhancement of interfacial adhesion between the ceramic stacked structure and the contact pad. Thus, electronic components formed by using the multilayer ceramic board in accordance with the present invention can prevent electrical leakage resistance, and improve RF circuit signal transmission power. Further, it can implement integrated pad line width, resulting in securing design freedom for mounting of a resistance, an inductor, and an MLCC.

Also, in case where the probe pins are formed on the multilayer ceramic board, the surfaces thereof can be protected from the chemicals used in the MEMS process of being a process for forming the probe pins. Therefore, it is possible to satisfy a contact resistance and an impedance matching, as well as to enhance bonding strength between the multilayer ceramic board and the probe pins, which contributes to manufacture of the probe card having superior electric characteristics.

In addition, in case where the probe pins are formed on the contact pads by the bonding process, the multilayer ceramic board is provided with the diffused reflection preventing patterns, so that it is possible to perform the alignment between the multilayer ceramic board and the probe pins although a separate pigment is not included in the ceramic stacked structure.

Hereinafter, with reference to FIGS. 10 to 12, a detailed description will be given of another method of manufacturing the multilayer ceramic board in accordance with the first embodiment of the present invention. This method is performed in the same manner as the above-described method of manufacturing the multilayer ceramic board, except for the formation of the diffused reflection preventing patterns. Therefore, a repeated description will be omitted, and the same component is indicated by the same reference numeral.

FIGS. 10 to 12 are cross-sectional views illustrating a method of manufacturing the multilayer ceramic board in accordance with a third embodiment of the present invention.

Referring to FIG. 10, in order to manufacture the multilayer ceramic board, a pre-ceramic stacked structure 110a formed by being staked with a plurality of ceramic layers is first provided. Herein, the interlayer connection is made in the pre-ceramic stacked structure 110a by the vias 122 provided in each of the ceramic layers 112 and 113.

Thereafter, the green sheets 211 and 214 having the diffused reflection preventing patterns 130 are provided on each of the both sides of the pre-ceramic stacked structure 110a.

In order to form the diffused reflection preventing patterns 130 on the green sheets 211 and 214, the vias 122 are formed by passing the green sheets 211 and 214. Herein, the inner circuit patterns 123 electrically connected to the vias 122 may be further formed on the green sheets 211 and 214.

On the green sheets 211 and 214, mask patterns (not shown) which cover the vias 122 are formed. The mask patterns may be formed through a printing method, e.g. a screen printing method, a roll printing method, an imprinting method, and so on. Further, the mask patterns may include at least one of a teflon-based resin and a silicon-based resin having superior thermal resistance.

Thereafter, the diffused reflection preventing material is deposited on the green sheets 211 and 214 having the mask patterns. Herein, the diffused reflection preventing material may be a material which absorbs lights and has superior chemical resistance, for example, a Diamond-like carborn (DLC), or a Silicon carbide (SiC).

Thereafter, by removing the mask patterns, the diffused reflection preventing patterns 130 are formed which exposes the vias 122 on the green sheets 211 and 214.

By stacking the green sheets 211 and 214 having the diffused reflection preventing patterns 130 which are provided on each of the both sides of the pre-ceramic stacked structure 110a, and performing a firing process, the ceramic stacked structure 110 having the diffused reflection preventing patterns 130 on each of the both sides thereof can be formed, as shown in FIG. 11.

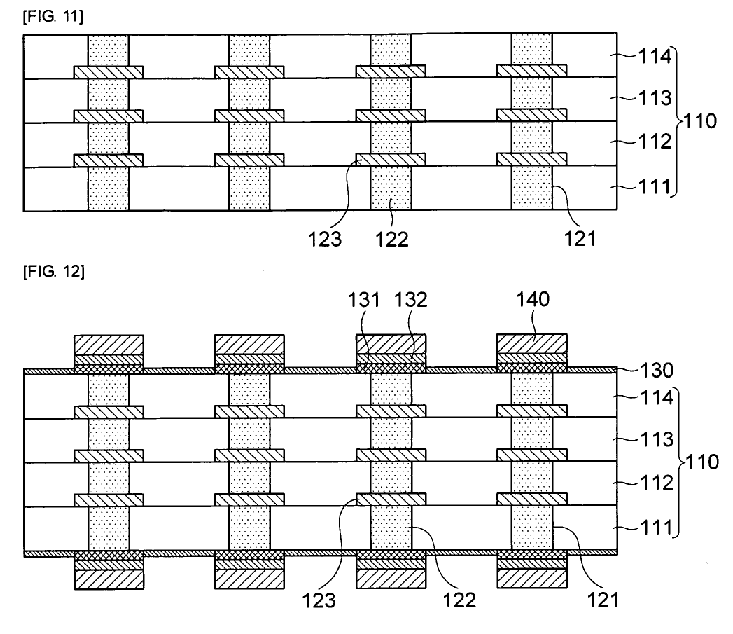

Referring to FIG. 12, after forming the diffused reflection preventing patterns 130, as described above, a deposition process for forming conductive adhesive layers and plating seed layers, a photo process for forming resist patterns, and a plating process are performed, so that it is possible to form the contact pads 140 connected to the vias 122 exposed from the diffused reflection preventing patterns 130.

Hereinafter, a description will be given of an effect of the multilayer ceramic board in accordance with the embodiment of the present invention, with Tables. Herein, the effect due to the formation of the diffused reflection preventing patterns has been proved by performing various tests whether or not the multilayer ceramic board has diffused reflection preventing patterns. In this case, an object to be implemented which is manufactured by the embodiment of the present invention has been formed to have the same structure as that of a comparative object to be tested, except that the diffused reflection prevention patterns have been further formed. Herein, the diffused reflection prevention patterns have been formed of a Diamond-like carborn.

Table 1 shows impedance values according to whether or not the diffused reflection preventing patterns are formed on the multilayer ceramic board.

TABLE 1

| | Impedance resistance (Ω) | | |
|---|---|---|---|
| | | | Object to be |
| Sample No | Design value | Comparative object | implemented |
| 1 | 50 | 61.28 | 50.61 |
| 2 | 50 | 62.48 | 50.1 |
| 3 | 50 | 62.93 | 50.19 |
| 4 | 50 | 64.75 | 50.76 |
| 5 | 50 | 63.21 | 50.53 |

As shown in Table 1, when the multilayer ceramic board is provided with the diffused reflection preventing patterns, impedance resistance has a value nearly similar to the design value. Therefore, it is possible to easily implement design of impedance matching.

Table 2 below shows its strength according to whether or not the diffused reflection preventing patterns are formed on the multilayer ceramic board.

TABLE 2

Strength (Mpa)

| Sample No | Comparative object | Object to be implemented |
|---|---|---|
| 1 | 25 | 35.9 |
| 2 | 24.6 | 35.1 |
| 3 | 26.8 | 37.8 |
| 4 | 26.4 | 33.9 |
| 5 | 24.9 | 35.7 |
| Average | 25.5 | 35.7 |

As shown in Table 2, when the multilayer ceramic board is provided with the diffused reflection preventing patterns, the strength of the multilayer ceramic board is improved.

Table 3 below shows sticking strength between the ceramic stacked structure and the contact pad according to whether or not the diffused reflection preventing patterns are formed on the multilayer ceramic board.

TABLE 3

Sticking strength (N/mm2)

| Sample No | Comparative object | Object to be implemented |
|---|---|---|
| 1 | 19.1 | 34.5 |
| 2 | 20.5 | 36.6 |
| 3 | 19.4 | 37.8 |
| 4 | 26.4 | 39.1 |
| 5 | 26.7 | 38.7 |
| Average | 22.4 | 37.3 |

As shown in Table 3, it can be found that when the multilayer ceramic board is provided with the diffused reflection preventing patterns, sticking strength between the ceramic stacked structure and the contact pad is improved.

Furthermore, it was carried out a chemical resistance test for the multilayer ceramic board of being the comparative object and the object to be implemented.

In the chemical resistance test, the multilayer ceramic board has been immersed in a 49 wt % HF solution for two hours, and then its surface state and an amount of reduced weight before and after immersion have been measured.

It can be found that the multilayer ceramic board of being the comparative object, i.e. the multilayer ceramic board having no the diffused reflection preventing patterns, has the damaged surfaces after the chemical resistance test. In this case, the amount of the reduced weight before and after chemical resistance test is decreased by about 12%. Meanwhile, it can be found that the multilayer ceramic board of being the object to be implemented, i.e. the multilayer ceramic board having the diffused reflection preventing patterns, has nearly no damaged surfaces after the chemical resistance test. In this case, the amount of the reduced weight before and after chemical resistance test is decreased by 1%.

It can be found that when the multilayer ceramic board is provided with the diffused reflection preventing patterns, the chemical resistance is improved.

Therefore, the multilayer ceramic board in accordance with the embodiment of the present invention is provided with the diffused reflection preventing patterns formed of a material which prevents diffused reflection and superior chemical resistance, so that alignment control can be performed. Further, it is possible to secure chemical resistance and durability of the multilayer ceramic board, which contributes to formation of electric components capable of securing electric characteristics and reliability.

The multilayer ceramic board in accordance with the present invention is provided with a diffused reflection preventing patterns which absorb lights, and thus ceramic layers constituting the multilayer ceramic board is not required to include a separate pigment. Therefore, it is possible to prevent reduction in chemical resistance and durability due to the pigment, and to perform alignment.

Also, the diffused reflection preventing patterns in accordance with the present invention are formed of a material having superior chemical resistance, so that a multilayer ceramic board can be protected from chemicals used in its process.

Also, the diffused reflection preventing patterns in accordance with the present invention are formed of a material having superior chemical resistance, so that it is possible to secure surface durability of the multilayer ceramic board, resulting in maintaining strength of the board even in a subsequent process, e.g. a photo process, a plating process, and an etching process.

Also, diffused reflection preventing patterns in accordance with the present invention are formed of a material having superior chemical resistance, and thus the surfaces of the multilayer ceramic board can be prevented from being damaged. Therefore, it is possible to achieve superior interfacial adhesion between the multilayer ceramic board and the contact pads, which results in prevention of electrical leakage resistance and improvement of RF circuit signal transmission power.

Also, diffused reflection preventing patterns in accordance with the present invention are formed of a material having superior chemical resistance, so that it is possible to implement integrated pad line width, which results in securing design freedom for mount of a resistance, an inductor, and an MLCC.

As described above, although the preferable embodiments of the present invention have been shown and described, it will be appreciated by those skilled in the art that substitutions, modifications and changes may be made in this embodiment without departing from the principles and spirit of the general inventive concept, the scope of which is defined in the appended claims and their equivalents.

1. A multilayer ceramic board comprising:
a ceramic stacked structure in which multiple ceramic layers are stacked and interconnected to one another through vias;
diffused reflection preventing patterns which expose the vias provided on each of the uppermost ceramic layer and the lowermost ceramic layer, and are disposed on each of a top surface and a bottom surface of the ceramic stacked structure; and
contact pads which are electrically connected to the vias exposed by the diffused reflection preventing patterns.

2. The multilayer ceramic board of claim 1, wherein the diffused reflection preventing patterns are composed of a Diamond-like carborn (DLC), or a Silicon carbide (SiC).

3. The multilayer ceramic board of claim 1, further comprising conductive adhesive patterns interposed between the contact pads and the vias.

4. The multilayer ceramic board of claim 3, wherein the conductive adhesive patterns include at least one of Ni, Ti, and Cr.

5. The multilayer ceramic board of claim 1, wherein the contact pads include at least one of Cu, Ni, and Au.

6. A method of manufacturing a multilayer ceramic board comprising:
providing a ceramic stacked structure in which multiple ceramic layers are stacked, and are interconnected to one another through vias;
forming diffused reflection preventing patterns which expose the vias provided on each of the uppermost ceramic layer and the lowermost ceramic layer, and are disposed on each of a top surface and a bottom surface of the ceramic stacked structure; and
forming contact pads which are electrically connected to the vias exposed by the diffused reflection preventing patterns.

7. The method of claim 6, wherein the forming the diffused reflection preventing patterns comprises:
forming mask patterns which cover the vias provided on each of the uppermost ceramic layer and the lowermost ceramic layer;
depositing a diffused reflection preventing material on a top surface and a bottom surface of the ceramic stacked structure having the mask patterns formed thereon; and
forming the diffused reflection preventing patterns by removing the mask patterns.

8. The method of claim 7, wherein the mask patterns include at least one of a teflon-based resin and a silicon-based resin.

9. The method of claim 6, wherein the forming the contact pads comprises:
forming plating seed layers on the ceramic stacked structure having the diffused reflection preventing patterns;
forming resist patterns on the plating seed layers; and
forming the contact pads by performing a plating process on the plating seed layers exposed by the resist patterns.

10. The method of claim 9, further comprising, before the forming the plating seed layers, forming conductive adhesive layers on the ceramic stacked structure having the diffused reflection preventing patterns.

11. The method of claim 9, wherein the conductive adhesive layers include at least one of Ni, Ti, and Cr.

12. The method of claim 9, further comprising, after the forming the contact pads;
removing the resist patterns; and
patterning the conductive adhesive layers and the plating seed layers.

13. The method of claim 9, wherein, in the forming the resist patterns, an align mark is further formed on an edge of the ceramic stacked structure.

14. The method of claim 6, wherein the diffused reflection preventing patterns are formed of a Diamond-like carborn (DLC), or a Silicon carbide (SiC).

15. A method of manufacturing a multilayer ceramic board comprising:
providing a ceramic stacked structure in which multiple ceramic layers are stacked;
stacking green sheets which have vias playing a role of performing interlayer connection between the ceramic stacked structure, and the diffused reflection preventing patterns on each of both sides of the ceramic stacked structure;
firing the ceramic stacked structure in which the green sheets are stacked; and
forming contact pads electrically connected to the vias exposed by the diffused reflection preventing patterns.

16. The method of claim 15, wherein the forming the green sheets comprises:
forming green sheets having the vias passing therethrough;
forming mask patterns which cover the vias on the formed green sheets;
depositing a diffused reflection preventing material on the formed green sheets having the mask patterns; and
removing the mask patterns.

17. The method of claim 16, wherein the mask patterns include at least one of a teflon-based resin and a silicon-based resin.

18. The method of claim 15, wherein the diffused reflection preventing patterns are formed of a Diamond-like carborn (DLC), or a Silicon carbide (SiC).
